(19) United States
(12) Patent Application Publication
(10) Pub. No.: US 2025/0241136 A1
(43) Pub. Date: Jul. 24, 2025

(54) DISPLAY DEVICE AND METHOD FOR MANUFACTURING THE DISPLAY DEVICE

(71) Applicant: Samsung Display Co., LTD., Yongin-si (KR)

(72) Inventors: Hyun Eok SHIN, Yongin-si (KR); Ju Hyun LEE, Yongin-si (KR); Dong Min LEE, Yongin-si (KR)

(21) Appl. No.: 18/830,476

(22) Filed: Sep. 10, 2024

(30) Foreign Application Priority Data
Jan. 23, 2024 (KR) 10-2024-0009915

(51) Int. Cl. H10K 59/122; H10K 59/12

(52) U.S. Cl. CPC H10K 59/122; H10K 59/1201

(57) ABSTRACT

A display device includes a substrate including an emission area and a non-emission area; a first bank layer positioned on the emission area of the substrate; a first bank insulating layer positioned on a side surface of the first bank layer; a second bank layer positioned on the first bank layer and including a tip protruding more than the side surface of the first bank layer toward the non-emission area; a pixel electrode positioned on the second bank layer; a light emitting layer positioned on the pixel electrode; a residual pattern positioned on the non-emission area of the substrate and spaced apart from the pixel electrode wherein the residual pattern and the pixel electrode include a same material; and a pixel defining layer positioned on the residual pattern and covering the first bank layer, the second bank layer, and the pixel electrode.

This application claims priority to Korean Patent Application No. 10-2024-0009915, filed on Jan. 23, 2024, and all the benefits accruing therefrom under 35 U.S.C. § 119, the content of which in its entirety is herein incorporated by reference.

### BACKGROUND

### Technical Field

The present disclosure relates to a display device and a method for manufacturing the display device.

### Description of the Related Art

As the information society develops, the demand for display devices for displaying images has increased and diversified. For example, display devices have been applied to various electronic devices such as, for example, smartphones, digital cameras, laptop computers, navigation devices, and smart televisions. The display devices may be flat panel display devices such as, for example, liquid crystal display devices, field emission display devices, or organic light emitting display devices. Among such flat panel display devices, a light emitting display device may display an image without a backlight unit providing light to a display panel because each of pixels of the display panel includes light emitting elements that may emit light by themselves.

Recently, display devices have been applied to glasses-type devices for providing virtual reality and augmented reality. A display device may be implemented in a very small size of 2 inches or less in order to be applied to the glasses-type device, but should have a high pixel integration degree in order to be implemented with high resolution. For example, the display device may have a high pixel integration degree of 1000 pixels per inch (PPI) or more.

When a display device is implemented in a very small size but has a high pixel integration degree as described herein, areas of emission areas where light emitting elements are disposed are reduced, and thus, it is difficult to implement light emitting elements separated from each other for each emission area through a mask process.

### SUMMARY

Aspects of the present disclosure provide a display device and a method of manufacturing the display device. The method may be capable of, with respect to the display device, forming pixel electrodes spaced apart from each other without a separate etching process and at the same time, solving a short-circuit defect caused by contact between the pixel electrodes and a bank structure.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Detailed contents of other embodiments are described in a detailed description and are illustrated in the drawings.

In an embodiment of the disclosure, a display device includes a substrate including an emission area and a non-emission area; a first bank layer positioned on the emission area of the substrate; a first bank insulating layer positioned on a side surface of the first bank layer; a second bank layer positioned on the first bank layer and including a tip protruding more than the side surface of the first bank layer toward the non-emission area; a pixel electrode positioned on the second bank layer; a light emitting layer positioned on the pixel electrode; a residual pattern positioned on the non-emission area of the substrate and spaced apart from the pixel electrode, wherein the residual pattern and the pixel electrode include a same material; and a pixel defining layer positioned on the residual pattern and covering the first bank layer, the second bank layer, and the pixel electrode.

In an embodiment, the light emitting layer may overlap the first bank layer and the second bank layer in a direction perpendicular to the substrate.

In an embodiment, an undercut may be formed between the side surface of the first bank layer and the tip of the second bank layer, and the undercut overlaps the light emitting layer in the direction perpendicular to the substrate.

In an embodiment, a height of the first bank layer may be greater than a height of the second bank layer.

In an embodiment, wherein the first bank layer and the second bank layer may include different respective metals or alloys.

In an embodiment, the first bank insulating layer entirely may cover the side surface of the first bank layer.

In an embodiment, the first bank insulating layer may overlap the light emitting layer in a direction parallel to the substrate.

In an embodiment, the first bank insulating layer may include fluorine ions.

In an embodiment, the first bank insulating layer may include either aluminum fluoride or aluminum oxide fluoride.

In an embodiment, the second bank layer may include a first surface facing the pixel electrode and a side surface facing the non-emission area, and the pixel electrode covers the side surface of the second bank layer.

In an embodiment, the pixel electrode may be in contact with the side surface of the second bank layer.

In an embodiment, the second bank layer may further include a second surface opposing the first surface, and a second bank insulating layer may be positioned on the second surface in a portion overlapping the tip of the second bank layer.

In an embodiment, the second bank insulating layer may overlap the light emitting layer in a direction parallel to the substrate, and the second bank insulating layer may include titanium oxide.

In an embodiment, the pixel defining layer entirely may cover the bank insulating layer and the tip of the second bank layer.

In an embodiment, the pixel electrode may include a first layer disposed on the second bank layer and including metal; and a second layer disposed on the first layer and including transparent conductive oxide (TCO).

In an embodiment, the residual pattern may include a first residual pattern a second residual pattern, wherein the first residual pattern and the first layer include a same first material, and the second residual pattern and the second layer include a same second material.

In an embodiment of the disclosure, a method of fabricating a display device includes forming a first bank layer on a substrate and forming a second bank layer on the first bank layer; removing portions of the second bank layer and the first bank layer; etching a portion of the first bank layer such that the second bank layer includes a tip protruding more than a side surface of the first bank layer; forming a bank insulating layer on the side surface of the first bank layer; and forming a pixel electrode on the second bank layer and forming a residual pattern on the substrate.

In an embodiment, in the forming of the bank insulating layer may include injecting fluorine ion gas or fluorine ion gas and oxygen gas.

In an embodiment, in the forming of the bank insulating layer, the bank insulating layer entirely may cover the side surface of the first bank layer.

In an embodiment, the forming of the pixel electrode on the second bank layer and the forming of the residual pattern on the substrate may include disconnecting a material forming the pixel electrode by the tip of the second bank layer, wherein disconnecting the material includes separating the material into the pixel electrode and the residual pattern.

With a display device and a method for manufacturing the same according to an embodiment, the display device includes a bank structure having undercut structures under pixel electrodes, such that a gap between the pixel electrodes may be reduced, and accordingly, a high-resolution display device may be implemented. In some aspects, the display device according to an embodiment includes a bank insulating layer on a side surface of the bank structure, such that a short-circuit defect caused by contact between the pixel electrode and the bank structure may be solved.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a head mounted electronic device according to an embodiment;

FIG. 2 is an exploded perspective view of the head mounted electronic device of FIG. 1;

FIG. 3 is a perspective view illustrating a head mounted electronic device according to another embodiment;

FIG. 4 is an exploded perspective view illustrating a display device according to an embodiment;

FIG. 5 is a schematic cross-sectional view of a display panel according to an embodiment taken along line X1-X1′ in FIG. 4;

FIG. 6 is an enlarged cross-sectional view of area A1 of FIG. 5;

FIG. 7 is an enlarged cross-sectional view of area A1 of FIG. 5 according to another embodiment;

FIG. 8 is a schematic cross-sectional view of a display panel according to another embodiment taken along line X1-X1′ in FIG. 4; and

FIGS. 9 to 17 are cross-sectional views sequentially illustrating manufacturing processes of a bank structure, pixel electrodes, and a pixel defining layer of a display panel according to an embodiment.

### DETAILED DESCRIPTION

The invention now will be described more fully hereinafter with reference to the accompanying drawings, in which various embodiments are illustrated. Aspects supported by the present disclosure may, however, be embodied in many different forms, and should not be construed as limited to the embodiments set forth herein. Rather, the example embodiments are provided such that this disclosure will be thorough and complete, and will fully convey the scope of example aspects of the present disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third,” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

The term “substantially,” as used herein, means approximately or actually. The term “substantially equal” means approximately or actually equal. The term “substantially the same” means approximately or actually the same.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

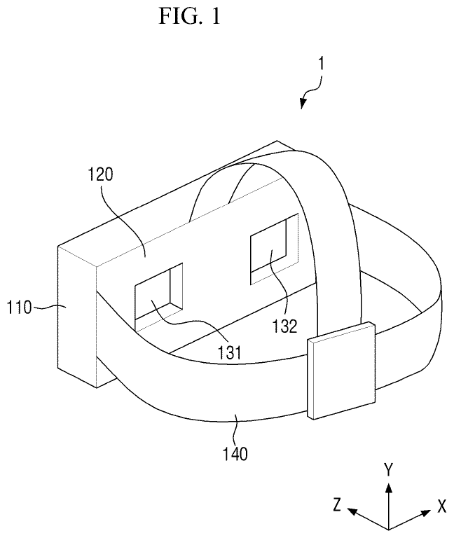

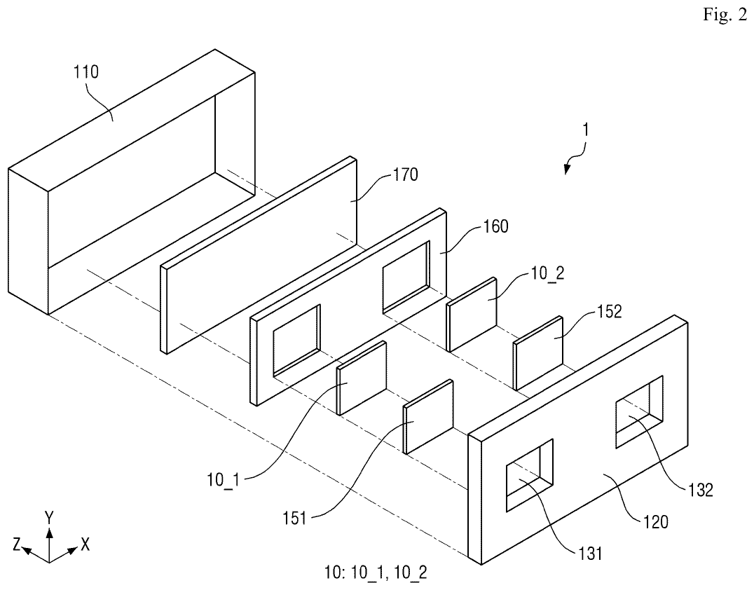

FIG. 1 is a perspective view illustrating a head mounted electronic device according to an embodiment. FIG. 2 is an exploded perspective view of the head mounted electronic device of FIG. 1.

Referring to FIGS. 1 and 2, a head mounted electronic device 1 according to an embodiment may include a display device 10, a display device housing portion 110, a housing portion cover 120, a first eyepiece 131, a second eyepiece 132, a head mounted band 140, a middle frame 160, a first optical member 151, a second optical member 152, and a control circuit board 170.

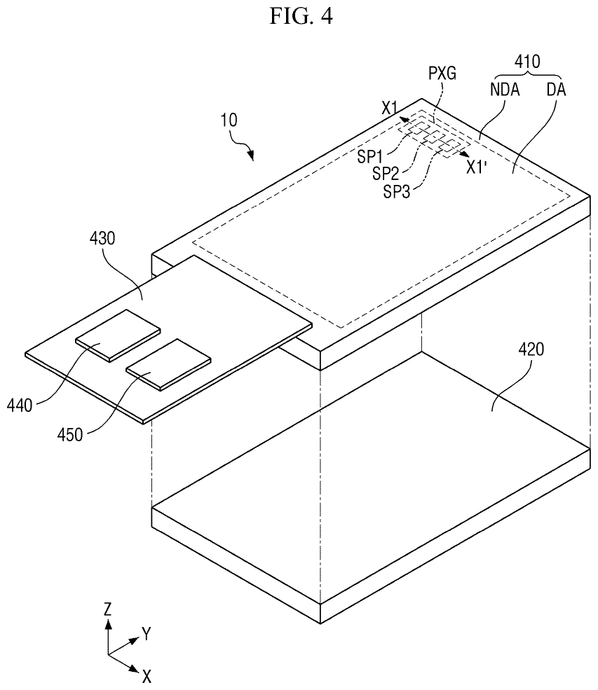

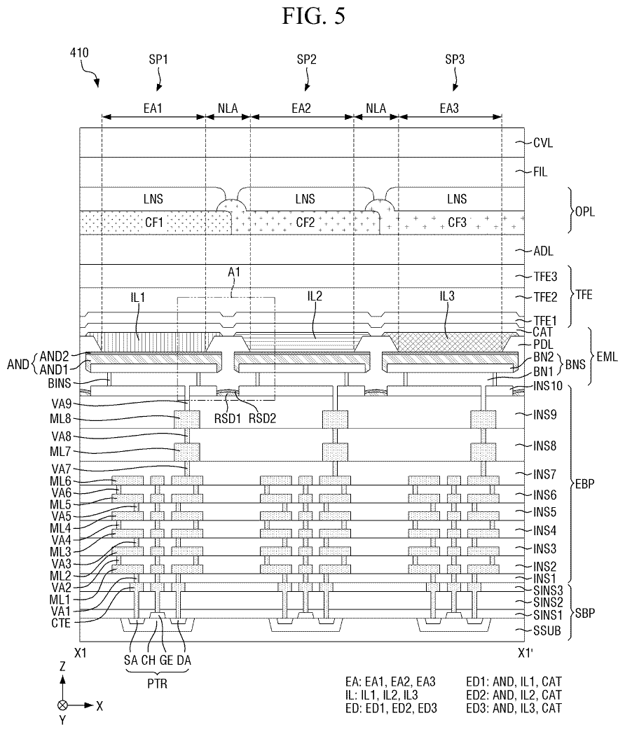

The display device 10 may include a first display device 10_1 and a second display device 10_2. The first display device 10_1 provides an image to a user's left eye, and the second display device 10_2 provides an image to a user's right eye. The display device 10 will be described in detail later with reference to FIGS. 4 and 5.

The first optical member 151 may be disposed between the first display device 10_1 and the first eyepiece 131, and the second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and disposed between the second display device 10_2 and the control circuit board 170. The middle frame 160 serves to support and fix the first display device 10_1, the second display device 10_2, and the control circuit board 170.

The control circuit board 170 may be disposed between the middle frame 160 and the display device housing portion 110. The control circuit board 170 may be connected to the first display device 10_1 and the second display device 10_2 through a connector. The control circuit board 170 may convert an image source input from the outside into digital video data, and transmit the digital video data to the first display device 10_1 and the second display device 10_2 through the connector.

The control circuit board 170 may transmit digital video data corresponding to a left eye image optimized for the user's left eye to the first display device 10_1 and transmit digital video data corresponding to a right eye image optimized for the user's right eye to the second display device 10_2. Alternatively, the control circuit board 170 may transmit the same digital video data to the first display device 10_1 and the second display device 10_2.

The display device housing portion 110 serves to house the display device 10, the middle frame 160, the first optical member 151, the second optical member 152, and the control circuit board 170. The housing portion cover 120 is disposed to cover opened one surface of the display device housing portion 110. The housing portion cover 120 may include the first eyepiece 131 on which the user's left eye is disposed and the second eyepiece 132 on which the user's right eye is disposed. It has been illustrated in FIGS. 1 and 2 that the first eyepiece 131 and the second eyepiece 132 are separately disposed, but embodiments of the present disclosure are not limited thereto. The first eyepiece 131 and the second eyepiece 132 may be merged as one eyepiece.

The first eyepiece 131 may be aligned with the first display device 10_1 and the first optical member 151, and the second eyepiece 132 may be aligned with the second display device 10_2 and the second optical member 152. Accordingly, a user may view an image of the first display device 10_1 magnified as a virtual image by the first optical member 151 through the first eyepiece 131, and may view an image of the second display device 10_2 magnified as a virtual image by the second optical member 152 through the second eyepiece 132.

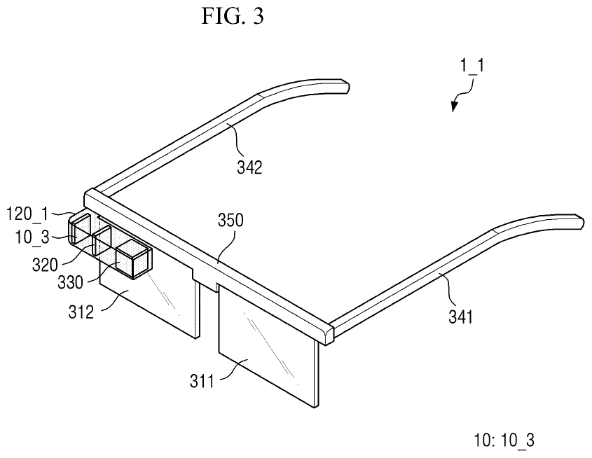

The head mounted band 140 serves to fix the display device housing portion 110 to a user's head such that the first eyepiece 131 and the second eyepiece 132 of the housing portion cover 1200 may be maintained in a state in which they are disposed on the user's left eye and right eye, respectively. In an example in which the display device housing portion 110 is implemented to have a light weight and a small size, the head mounted electronic device 1 may include an eyeglass frame as illustrated in FIG. 3 instead of the head mounted band 140.

In some aspects, the head mounted electronic device 1 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity (WiFi) module, or a Bluetooth module.

FIG. 3 is a perspective view illustrating a head mounted electronic device according to another embodiment.

Referring to FIG. 3, a head mounted electronic device 1_1 according to another embodiment may be a glasses-type electronic device in which a display device housing portion 120_1 is implemented to have a light weight and a small size. The head mounted electronic device 1_1 according to another embodiment may include a display device 10, a left eye lens 311, a right eye lens 312, a support frame 350, glasses frame legs 341 and 342, an optical member 320, an optical path conversion member 330, and a display device housing portion 120_1.

The display device 10 illustrated in FIG. 3 may include a third display device 10_3. The third display device 10_3 may be substantially the same as the first display device 10_1 and the second display device 10_2 illustrated in FIG. 2. The display device 10 will be described later with reference to FIGS. 4 and 5.

The display device housing portion 120_1 may include the display device 10, the optical member 320, and the optical path conversion member 330. An image displayed on the display device 10 may be magnified by the optical member 320, converted in an optical path by the optical path conversion member 330, and provided to a user's right eye through the right eye lens 312. For this reason, a user may view an augmented reality image in which a virtual image displayed on the display device 10 through his/her right eye and a real image seen through the right eye lens 312 are combined with each other.

It has been illustrated in FIG. 3 that the display device housing portion 120_1 is disposed at a right end of the support frame 350, but embodiments of the present disclosure are not limited thereto. For example, the display device housing portion 120_1 may be disposed at a left end of the support frame 350, and in this case, an image of the display device 10 may be provided to a user's left eye. Alternatively, the display device housing portions 120_1 may be disposed at both the left and right ends of the support frame 350, and in this case, the user may view an image displayed on the display device 10 through both his/her left and right eyes.

FIG. 4 is an exploded perspective view illustrating a display device 10 according to an embodiment.

Referring to FIG. 4, the display device 10 according to an embodiment is a device that displays a moving image or a still image. The display device 10 according to an embodiment may be applied to portable electronic devices such as, for example, mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 may be applied as a display unit of televisions, laptop computers, monitors, billboards, or the Internet of Things (IOTs). Alternatively, the display device 10 may be applied to smart watches, watch phones, or head mounted displays (HMDs) for realizing virtual reality and augmented reality.

The display device 10 according to an embodiment includes a display panel 410, a heat dissipation layer 420, a circuit board 430, a driving circuit 440, and a power supply circuit 450.

The display panel 410 may have a shape similar to a rectangular shape in plan view. For example, the display panel 410 may have a shape similar to a rectangular shape, in plan view, having short sides in a first direction X and long sides in a second direction Y crossing the first direction X. In the display panel 410, a corner where the short side in the first direction X and the long side in the second direction Y meet may be rounded with a predetermined curvature or right-angled. The shape of the display panel 410 in plan view is not limited to the rectangular shape, and may be a shape similar to other polygonal shapes, a circular shape, or an elliptical shape. A shape of the display device 10 in plan view may follow the shape of the display panel 410 in plan view, but embodiments of the present disclosure are not limited thereto.

A display area DA may be positioned at the center of the display panel 410, and may occupy most of an area of the display panel 410. The display area DA may include pixel groups PXG, and the pixel group PXG may be a minimum unit emitting white light. The pixel group PXG may include a plurality of first to third pixels SP1, SP2, and SP3. The first to third pixels SP1, SP2, and SP3 may emit light of the same color or emit light of different colors. A non-display area NDA may surround an edge of the display area DA.

The heat dissipation layer 420 may overlap the display panel 410 in a third direction Z, which is a thickness direction of the display panel 410. The heat dissipation layer 420 may be disposed on one surface, for example, a rear surface, of the display panel 410. The heat dissipation layer 420 serves to dissipate heat generated from the display panel 410. The heat dissipation layer 420 may include a layer formed of graphite or metal such as, for example, silver (Ag), copper (Cu), or aluminum (Al) having high thermal conductivity.

The circuit board 430 may be positioned on the non-display area NDA of the display panel 410 using a conductive adhesive member such as, for example, an anisotropic conductive film. The circuit board 430 may be a flexible printed circuit board or a flexible film having a flexible material. It has been illustrated in FIG. 4 that the circuit board 430 is unbent, but the circuit board 430 may be bent. In this case, one end of the circuit board 430 may be disposed on the rear surface of the display panel 410. One end of the circuit board 430 may be an end opposite to the other end of the circuit board 430 connected to a plurality of pads of a pad area of the display panel 410 using the conductive adhesive member.

The driving circuit 440 may receive digital video data and timing signals from the outside. The driving circuit 440 may generate a scan timing control signal, an emission timing control signal, and a data timing control signal for controlling the display panel 410 according to the timing signals.

The power supply circuit 450 may generate a plurality of panel driving voltages according to an external source voltage. For example, the power supply circuit 450 may generate a first driving voltage (e.g., VSS), a second driving voltage (e.g., VDD), and a third driving voltage (e.g., VINT) and supply the first driving voltage, the second driving voltage, and the third driving voltage to the display panel 410.

Each of the driving circuit 440 and the power supply circuit 450 may be formed as an integrated circuit (IC) and attached to one surface of the circuit board 430.

FIG. 5 is a schematic cross-sectional view of a display panel according to an embodiment taken along line X1-X1′ in FIG. 4.

Referring to FIG. 5, the display panel 410 includes a semiconductor backplane SBP, a light emitting element backplane EBP, a light emitting element layer EML, an encapsulation layer TFE, an optical layer OPL, and a cover layer CVL.

The semiconductor backplane SBP may include a semiconductor substrate SSUB including a plurality of transistors PTR, a plurality of semiconductor insulating films covering the plurality of transistors PTR, and a plurality of contact terminals CTE electrically connected to the plurality of transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well regions may be disposed in an upper surface of the semiconductor substrate SSUB. The plurality of well regions may be regions doped with second-type impurities. The second-type impurities may be different from the first-type impurities described herein. In an example in which the first-type impurities are p-type impurities, the second-type impurities may be n-type impurities. Alternatively, when the first-type impurities are n-type impurities, the second-type impurities may be p-type impurities.

Each of the plurality of well regions includes a source region SA corresponding to a source electrode of the transistor PTR, a drain region DA corresponding to a drain electrode of the transistor PTR, and a channel region CH disposed between the source region SA and the drain region DA.

Each of the source region SA and the drain region DA may be a region doped with the first-type impurities. A gate electrode GE of the transistor PTR may overlap the well region in the third direction Z. The channel region CH may overlap the gate electrode GE in the third direction Z. The source region SA may be disposed on one side of the gate electrode GE, and the drain region SA may be disposed on the other side of the gate electrode GE.

A first insulating layer SINS1 may be disposed on the semiconductor substrate SSUB. The first insulating layer SINS1 may be formed as a silicon carbonitride (SiCN) or silicon oxide (SiOₓ)-based inorganic film, but embodiments of the present disclosure are not limited thereto.

A second insulating layer SINS2 may be disposed on the first insulating layer SINS1. The second insulating layer SINS2 may be formed as a silicon oxide (SiOₓ)-based inorganic film, but embodiments of the present disclosure are not limited thereto.

The plurality of contact terminals CTE may be disposed on the second insulating layer SINS2. Each of the plurality of contact terminals CTE may be connected to any one of the gate electrode GE, the source region SA, and the drain region DA of each of the transistors PTR through a hole penetrating through the first insulating layer SINS1 and the second insulating layer SINS2.

Each of the contact terminals CTE may be formed of any one of copper (Cu), aluminum (Al), tungsten (W), molybdenum (Mo), chromium (Cr), gold (Au), titanium (Ti), nickel (Ni), and neodymium (Nd), or alloys thereof.

A third insulating layer SINS3 may be disposed on side surfaces of the contact terminals CTE. An upper surface of each of the plurality of contact terminals CTE may be exposed without being covered by the third insulating layer SINS3. The third insulating layer SINS3 may be formed as a silicon oxide (SiOₓ)-based inorganic film, but embodiments of the present disclosure are not limited thereto.

The semiconductor substrate SSUB may be replaced with a glass substrate or a polymer resin substrate such as, for example, a polyimide substrate. In this case, thin film transistors may be disposed on the glass substrate or the polymer resin substrate. The glass substrate may be a rigid substrate that is not bent, and the polymer resin substrate may be a flexible substrate that may be bent or curved.

The light emitting element backplane EBP includes first to eighth metal layers ML1 to ML8, a plurality of vias VA1 to VA10, and a plurality of interlayer insulating layers INS1 to INS10.

The first to eighth metal layers ML1 to ML8 serve to implement circuits of the pixels SP1 to SP3 by connecting the plurality of contact terminals CTE exposed from the semiconductor backplane SBP to each other.

A first interlayer insulating layer INS1 may be disposed on the semiconductor backplane SBP. Each of first vias VA1 may penetrate through the first interlayer insulating layer INS1 and be connected to the contact terminal CTE exposed from the semiconductor backplane SBP. Each of the first metal layers ML1 may be disposed on the first interlayer insulating layer INS1 and be connected to the first via VA1.

A second interlayer insulating layer INS2 may be disposed on the first interlayer insulating layer INS1 and the first metal layers ML1. Each of second vias VA2 may penetrate through the second interlayer insulating layer INS2 and be connected to the exposed first metal layer ML1. Each of the second metal layers ML2 may be disposed on the second interlayer insulating layer INS2 and be connected to the second via VA2.

A third interlayer insulating layer INS3 may be disposed on the second interlayer insulating layer INS2 and the second metal layers ML2. Each of third vias VA3 may penetrate through the third interlayer insulating layer INS3 and be connected to the exposed second metal layer ML2. Each of the third metal layers ML3 may be disposed on the third interlayer insulating layer INS3 and be connected to the third via VA3.

A fourth interlayer insulating layer INS4 may be disposed on the third interlayer insulating layer INS3 and the third metal layers ML3. Each of fourth vias VA4 may penetrate through the fourth interlayer insulating layer INS4 and be connected to the exposed third metal layer ML3. Each of the fourth metal layers ML4 may be disposed on the fourth interlayer insulating layer INS4 and be connected to the fourth via VA4.

A fifth interlayer insulating layer INS5 may be disposed on the fourth interlayer insulating layer INS4 and the fourth metal layers ML4. Each of fifth vias VA5 may penetrate through the fifth interlayer insulating layer INS5 and be connected to the exposed fourth metal layer ML4. Each of the fifth metal layers ML5 may be disposed on the fifth interlayer insulating layer INS5 and be connected to the fifth via VA5.

A sixth interlayer insulating layer INS6 may be disposed on the fifth interlayer insulating layer INS5 and the fifth metal layers ML5. Each of sixth vias VA6 may penetrate through the sixth interlayer insulating layer INS6 and be connected to the exposed fifth metal layer ML5. Each of the sixth metal layers ML6 may be disposed on the sixth interlayer insulating layer INS6 and be connected to the sixth via VA6.

A seventh interlayer insulating layer INS7 may be disposed on the sixth interlayer insulating layer INS6 and the sixth metal layers ML6. Each of seventh vias VA7 may penetrate through the seventh interlayer insulating layer INS7 and be connected to the exposed sixth metal layer ML6. Each of the seventh metal layers ML7 may be disposed on the seventh interlayer insulating layer INS7 and be connected to the seventh via VA7.

An eighth interlayer insulating layer INS8 may be disposed on the seventh interlayer insulating layer INS7 and the seventh metal layers ML7. Each of eighth vias VA8 may penetrate through the eighth interlayer insulating layer INS8 and be connected to the exposed seventh metal layer ML7. Each of the eighth metal layers ML8 may be disposed on the eighth interlayer insulating layer INS8 and be connected to the eighth via VA8.

The contact terminals CTE of the semiconductor backplane SBP and the first to sixth metal layers ML1 to ML6 of the light emitting element backplane EBP may be connected to the drain region DA, the source region SA, and the gate electrode GE of the transistor PTR. In an example, the seventh and eighth metal layers ML7 and ML8 are connected to the source region SA and the gate electrode GE, but may be connected to the drain region DA.

The first to eighth metal layers ML1 to ML8 and the first to eighth vias VA1 to VA8 may be formed of substantially the same material. Each of the first to eighth metal layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or alloys thereof. The first to eighth vias VA1 to VA8 may be formed of substantially the same material. The first to eighth interlayer insulating layers INS1 to INS8 may be formed as silicon oxide (SiOₓ)-based inorganic films, but embodiments of the present disclosure are not limited thereto.

A ninth interlayer insulating layer INS9 may be disposed on the eighth interlayer insulating layer INS8 and the eighth metal layers ML8. The ninth interlayer insulating layer INS9 may be formed as a silicon oxide (SiOₓ)-based inorganic film, but embodiments of the present disclosure are not limited thereto.

Each of ninth vias VA9 may penetrate through the ninth interlayer insulating layer INS9 and be connected to the exposed eighth metal layer ML8. Each of the ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or alloys thereof.

Tenth interlayer insulating layers INS10 may be disposed on the ninth interlayer insulating layer INS9. The tenth interlayer insulating layer INS10 may overlap a pixel electrode AND of an emission area EA to be described later, and the respective tenth interlayer insulating layers INS10 may be spaced apart from each other. The tenth interlayer insulating layer INS10 may be formed as a silicon nitride (SiNx)-based inorganic film, but embodiments of the present disclosure are not limited thereto. The ninth vias VA9 may penetrate through the tenth interlayer insulating layer INS10.

The light emitting element layer EML may be disposed on the light emitting element backplane EBP. The light emitting element layer EML may include a bank structure BNS, a bank insulating layer BINS, a light emitting element ED, first and second residual patterns RSD1 and RSD2, and a pixel defining layer PDL.

The display panel 410 according to an embodiment may include an emission area EA and a non-emission area NLA. The emission area EA and the non-emission area NLA may be positioned within the display area DA in FIG. 4.

The emission area EA may include a first emission area EA1, a second emission area EA2, and a third emission area EA3 that emit light of different colors. The first to third emission areas EA1, EA2, and EA3 may emit red, green, or blue light, respectively, and colors of the light emitted from the first to third emission areas EA1, EA2, and EA3 may be different from each other depending on types of light emitting elements ED to be described later. In an embodiment, the first emission area EA1 may emit the red light, which is light of a first light, the second emission area EA2 may emit the green light, which is light of a second color, and the third emission area EA3 may emit the blue light, which is light of a third color, but embodiments of the present disclosure are not limited thereto.

The first pixel SP1 may be positioned in a portion overlapping the first emission area EA1, the second pixel SP2 may be positioned in a portion overlapping the second emission area EA2, and the third pixel SP3 may be positioned in a portion overlapping the third emission area EA3.

The non-emission area NLA may assist in preventing each light emitted from the first to third emission areas EA1, EA2, and EA3 from being mixed with each other. The pixel defining layer PDL may be positioned in the non-emission area NLA.

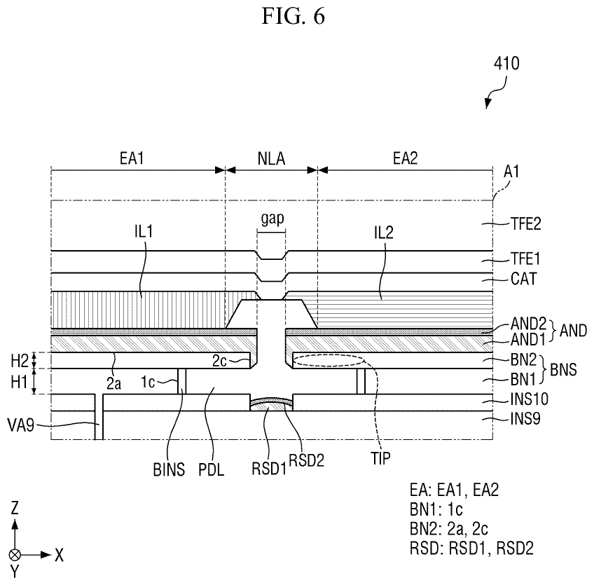

FIG. 6 is an enlarged view of area A1 of FIG. 5, and illustrates the bank structure BNS, the bank insulating layer BINS, the light emitting element ED, and the pixel defining layer PDL of the light emitting element layer EML in more detail.

Referring to FIGS. 5 and 6, the bank structure BNS may be disposed on the tenth interlayer insulating layer INS10. The bank structure BNS may be positioned in a portion overlapping the emission area EA. The bank structure BNS may include a first bank layer BN1 and a second bank layer BN2 that are sequentially stacked.

The first bank layer BN1 according to an embodiment may be disposed on the tenth interlayer insulating layer INS10. The first bank layer BN1 may be connected to the ninth via VA9. The first bank layer BN1 and the ninth via VA9 may include the same material.

The first bank layer BN1 may include a plurality of patterns, and the respective patterns may be separated or spaced apart from each other in the first direction X in portions overlapping the first to third emission areas EA1, EA2, and EA3. That is, the first bank layer BN1 may have island patterns. Each island of the first bank layer BN1 may have a circular shape or a polygonal shape such as, for example, a triangular shape or a rectangular shape in plan view.

In some embodiments, the first bank layer BN1 may include a side surface 1c. The side surface 1c of the first bank layer BN1 may face the bank insulating layer BINS. The side surface 1c of the first bank layer BN1 may be depressed (recessed) more than a side surface 2c of the second bank layer BN2 toward the center of the emission area EA.

The second bank layer BN2 according to an embodiment may be disposed on the first bank layer BN1. The second bank layer BN2 may include a plurality of patterns, and the respective patterns may be separated or spaced apart from each other in the first direction X in the portions overlapping the first to third emission areas EA1, EA2, and EA3. In an embodiment, the second bank layer BN2 may have island patterns. Each island of the second bank layer BN2 may have a circular shape or a polygonal shape such as, for example, a triangular shape or a rectangular shape in plan view.

The first bank layer BN1 and the second bank layer BN2 according to an embodiment may include different materials. In other words, the first bank layer BN1 and the second bank layer BN2 may respectively include materials having different etch ratios, and the second bank layer BN2 may include a material having a lower etch rate than the first bank layer BN1. As an example, the first bank layer BN1 may include aluminum (Al) or an aluminum alloy, and the second bank layer BN2 may include titanium (Ti) or a titanium alloy.

In some embodiments, the second bank layer BN2 may include the side surface 2c. The side surface 2c of the second bank layer BN2 may protrude more than the side surface 1c of the first bank layer BN1 in the first direction X. As described herein, in a manufacturing process of the bank structure BNS, the first bank layer BN1 may include a material having a higher etch rate than the second bank layer BN2. For this reason, the second bank layer BN2 may have a tip TIP protruding more than the side surface 1c of the first bank layer BN1 in the first direction X, and an undercut may be formed between the side surface 1c of the first bank layer BN1 and the tip TIP of the second bank layer BN2.

In some embodiments, a height H2 of the second bank layer BN2 may be smaller than a height H1 of the first bank layer BN1.

The bank insulating layer BINS according to an embodiment may be disposed on the side surface 1c of the first bank layer BN1. The bank insulating layer BINS may be in entire contact with the side surface 1c of the first bank layer BN1, and may entirely cover the side surface 1c of the first bank layer BN1.

The bank insulating layer BINS may be formed by injecting fluorine-based gas and oxygen gas after the bank structure BNS is formed in a manufacturing process. Accordingly, the bank insulating layer BINS may include aluminum fluoride (AlFx) and aluminum oxide fluoride (AlOₓF_{y}). The manufacturing process will be described later.

The bank insulating layer BINS may solve or prevent a short-circuit defect from occurring due to contact between a material forming the pixel electrode AND according to an embodiment and a material forming the first bank layer BN1 in a manufacturing process of the display panel 410. For convenience of explanation, it has been illustrated that the bank insulating layer BINS covers the side surface 1c of the first bank layer BN1 at a uniform thickness, but embodiments of the present disclosure are not limited thereto. The bank insulating layer BINS may entirely cover the side surface 1c of the first bank layer BN1 and have various thicknesses. For example, the bank insulating layer BINS may have various thicknesses at respective portions of the bank insulating layer BINS in contact with the side surface 1c of the first bank layer BN1.

The light emitting element ED according to an embodiment may be disposed on the second bank layer BN2. The light emitting element ED may include a first light emitting element ED1 disposed in the first emission area EA1, a second light emitting element ED2 disposed in the second emission area EA2, and a third light emitting element ED3 disposed in the third emission area EA3. The first light emitting element ED1 may include a pixel electrode AND, a first light emitting layer IL1, and a common electrode CAT, the second light emitting element ED2 may include a pixel electrode AND, a second light emitting layer IL2, and a common electrode CAT, and the third light emitting element ED3 may include a pixel electrode AND, a third light emitting layer IL3, and a common electrode CAT.

The first to third light emitting elements ED1, ED2, and ED3 overlapping the first to third emission areas EA1, EA2, and EA3, respectively, may emit light of different colors depending on materials of a light emitting layer IL. For example, the first light emitting element ED1 may emit red light, which is light of a first light, the second light emitting element ED2 may emit green light, which is light of a second color, and the third light emitting element ED3 may emit blue light, which is light of a third color. However, embodiments of the present disclosure are not limited thereto, and the first to third light emitting elements ED1, ED2, and ED3 overlapping the first to third emission areas EA1, EA2, and EA3, respectively, may also emit light of the same color.

The pixel electrode AND according to an embodiment may be disposed on the second bank layer BN2. The pixel electrode AND may be electrically connected to the ninth via VA9 through the bank structure BNS having conductivity, and be then connected to the drain region DA or source region SA of the transistor PTR through the first to eighth vias VA1 to VA8, the first to eighth metal layers ML1 to ML8, and the contact terminal CTE.

The pixel electrode AND may include a first layer AND1 including metal and a second layer AND2 disposed on the first layer AND1 and including transparent conductive oxide (TCO).

As an example, the first layer AND1 may include any one of copper (Cu), aluminum (Al), tungsten (W), molybdenum (Mo), chromium (Cr), gold (Au), titanium (Ti), nickel (Ni), and neodymium (Nd), and the second layer AND2 may include one or more of indium tin oxide (ITO), indium zinc oxide (IZO), indium tin zinc oxide (ITZO), zinc indium tin oxide (ZITO), indium gallium zinc oxide (IGZO), and zinc tin oxide (ZTO). It has been illustrated in FIGS. 5 and 6 that the pixel electrode AND has a multilayer structure, but the pixel electrode AND may also be formed to have a single-layer structure according to embodiments.

The display panel 410 according to an embodiment includes the bank structure BNS forming the undercuts under the pixel electrodes AND, and thus, the pixel electrodes AND positioned to overlap the first to third emission areas EA1, EA2, and EA3 may be formed without a separate etching process. In other words, in the display panel 410 according to an embodiment, the second bank layer BN2 includes the tips TIP protruding more than the first bank layer BN1, and thus, a plurality of pixel electrodes AND positioned to be spaced apart from each other may be formed without a separate etching process. For this reason, in the display panel 410 according to an embodiment, the plurality of pixel electrodes AND neighboring to each other may be formed to have a very small gap between each other, and the display panel 410 according to an embodiment may be applied to an electronic device capable of providing high resolution.

In some embodiments, the pixel electrode AND according to an embodiment may be disposed not only on an upper surface 2a of the second bank layer BN2 but also on the side surface 2c of the second bank layer BN2. The pixel electrode AND may cover the side surface 2c of the second bank layer BN2, and may be in contact with the side surface 2c of the second bank layer BN2. The manufacturing process will be described later.

A residual pattern RSD according to an embodiment may be disposed on the ninth interlayer insulating layer INS9 in a portion overlapping the non-emission area NLA. The residual pattern RSD may be a result formed while a material forming the pixel electrode AND is disconnected from the pixel electrode AND rather than being connected to the pixel electrode AND, by the tip of the second bank layer BN2 in a manufacturing process of the pixel electrode AND. For example, in a manufacturing process of the pixel electrode AND, the material forming the pixel electrode AND may be divided into separate portions due to the tip of the second bank layer BN2.

The residual pattern RSD may include the same material as the pixel electrode AND. Accordingly, when the pixel electrode AND has the multilayer structure, the residual pattern RSD may also have a multilayer structure, and a stacked structure of the residual pattern RSD may be the same as a stacked structure of the pixel electrode AND. As an example, the residual pattern RSD may include the first residual pattern RSD1 and the second residual pattern RSD2, in which the first residual pattern RSD1 and the first layer AND1 of the pixel electrode AND may include a same first material, and the second residual pattern RSD2 and the second layer AND2 of the pixel electrode AND may include a same second material. For example, the residual pattern RSD may include the first residual pattern RSD1 including the same first material as the first layer AND1 of the pixel electrode AND and the second residual pattern RSD2 including the same second material as the second layer AND2 of the pixel electrode AND.

The residual pattern RSD may be disposed between a plurality of tenth interlayer insulating layers INS10 in the first direction X. The residual pattern RSD may be disposed at a lower position or level than the second bank layer BN2.

The pixel defining layer PDL according to an embodiment may be positioned on the tenth interlayer insulating layer INS10 and the residual pattern RSD. The pixel defining layer PDL may be positioned in a portion overlapping the non-emission area NLA. The bank structures BNS and the pixel electrodes AND according to an embodiment may be insulated and spaced apart from each other in the first direction X with the pixel defining layer PDL interposed the bank structures BNS and the pixel electrodes AND.

In some embodiments, the pixel defining layer PDL may be in contact with the residual pattern RSD, the bank insulating layer BINS, the tip TIP of the second bank layer BN2, and the pixel electrode AND. In some aspects, the pixel defining layer PDL may cover the undercut formed on the side surface 1c of the first bank layer BN1 and under the tip of the second bank layer BN2.

The pixel defining layer PDL may include an inorganic insulating material, for example, at least one of silicon nitride, silicon oxynitride, silicon oxide, titanium oxide, aluminum oxide, tantalum oxide, hafnium oxide, zinc oxide, and amorphous silicon, but is not limited thereto.

The light emitting layer IL according to an embodiment may be positioned on the pixel electrode AND and the pixel defining layer PDL. The light emitting layer IL may be positioned in a portion overlapping the emission area EA and the non-emission area NLA. The light emitting layer IL may be above the bank structure BNS and the first bank insulating layer BINS1 in the third direction (Z-axis direction). In other words, the light emitting layer IL may be above the first bank layer BN1 and the second bank layer BN2 in the third direction (Z-axis direction).

The light emitting layer IL according to an embodiment may include a first light emitting layer IL1, a second light emitting layer IL2, and a third light emitting layer IL3 positioned to respectively overlap the first to third emission areas EA1, EA2, and EA3. The first to third light emitting layers IL1, IL2, and IL3 may emit different light. For example, the first light emitting layer ILL disposed in the first emission area EA1 may emit red light having a peak wavelength in the range of 610 nm to 650 nm, the second light emitting layer IL2 disposed in the second emission area EA2 may emit green light having a peak wavelength in the range of 510 nm to 550 nm, and the third light emitting layer IL3 disposed in the third emission area EA3 may emit blue light having a peak wavelength in the range of 440 nm to 480 nm. The first to third emission areas EA constituting one pixel may include the light emitting elements emitting light of different colors to express a white gradation. Alternatively, the light emitting layer IL includes a plurality of materials emitting light of different colors, such that a single light emitting layer may emit mixed light.

The common electrode CAT according to an embodiment may be disposed on the light emitting layer IL and the pixel defining layer PDL. The common electrode CAT may be positioned in a portion overlapping the emission area EA and the non-emission area NLA. In other words, the common electrode CAT may be entirely formed.

The common electrode CAT may include a transparent conductive material to emit the light generated from the light emitting layer IL. The common electrode CAT may receive a common voltage or a low potential voltage. In an example in which the pixel electrode AND receives a voltage corresponding to a data voltage and the common electrode CAT receives the low potential voltage, a potential difference is formed between the pixel electrode AND and the common electrode CAT, such that the light emitting layer IL may emit the light. As an example, the common electrode CAT may be formed of a transparent conductive material (TCO) such as, for example, ITO or IZO capable of transmitting light therethrough or a semi-transmissive conductive material such as, for example, magnesium (Mg), silver (Ag), or an alloy of magnesium (Mg) and silver (Ag). In an example in which the common electrode CAT is formed of the semi-transmissive conductive material, light emission efficiency of each of the first to third pixels SP1, SP2, and SP3 may be increased by a micro cavity.

The encapsulation layer TFE may be disposed on the light emitting element layer EML. The encapsulation layer TFE may include at least one inorganic film in order to prevent oxygen or moisture from permeating into the light emitting element layer EML. In some aspects, the encapsulation layer TFE may include at least one organic film in order to protect the light emitting element layer EML from foreign substances such as, for example, dust. The encapsulation layer TFEL may include a first encapsulation layer TFE1, a second encapsulation layer TFE2, and a third encapsulation layer TFE3 that are sequentially stacked. The first encapsulation layer TFE1 may be disposed on the common electrode CAT, the second encapsulation layer TFE2 may be disposed on the first encapsulation layer TFE1, and the third encapsulation layer TFE3 may be disposed on the second encapsulation layer TFE2.

The first encapsulation layer TFE1 and the third encapsulation layer TFE3 may be formed of an inorganic insulating material. As an example, the first encapsulation layer TFE1 and the third encapsulation layer TFE3 may include silicon nitride (SiNₓ), silicon oxynitride (SiON), silicon oxide (SiOₓ), titanium oxide (TiOₓ), and aluminum oxide (AlOₓ).

The second encapsulation layer TFE2 may be formed of an organic material. As an example, the second encapsulation layer TFE2 may include an acrylic resin, an epoxy resin, a silicone resin, a silicone acrylic resin, a phenolic resin, a polyamide resin, a polyimide resin, or the like.

An adhesive layer ADL may be a layer for adhering the encapsulation layer TFE and the optical layer OPL to each other. The adhesive layer ADL may be a double-sided adhesive member. In some aspects, the adhesive layer ADL may be a transparent adhesive member such as, for example, a transparent adhesive or a transparent adhesive resin.

The optical layer OPL may include a plurality of first to third color filters CF1, CF2, and CF3, a plurality of lenses LNS, and a filling layer FIL.

The first to third color filters CF1, CF2, and CF3 may be disposed on the adhesive layer ADL. The first to third color filters CF1, CF2, and CF3 may include colorants such as, for example, dyes or pigments absorbing light of wavelength bands other than light of a specific wavelength band, and may be disposed to correspond to the colors of the light emitting from the emission areas EA.

The first color filter CF1 may be a red color filter disposed to overlap the first emission area EA1 and transmitting only the red light therethrough. The second color filter CF2 may be a green color filter disposed to overlap the second emission area EA2 and transmitting only the green light therethrough, and the third color filter CF3 may be a blue color filter disposed to overlap the third emission area EA3 and transmitting only the blue light therethrough.

The plurality of lenses LNS may be disposed on the first color filter CF1, the second color filter CF2, and the third color filter CF3, respectively. The plurality of lenses LNS may be structures for increasing a ratio of light directed to a front surface of the display panel 410 (also referred to herein as a display device). The plurality of lenses LNS may have a cross-sectional shape convex in an upward direction.

The filling layer FIL may be disposed on the plurality of lenses LNS. The filling layer FIL may have a predetermined refractive index such that light travels in the third direction Z at an interface between the plurality of lenses LNS and the filling layer FIL. In some aspects, the filling layer FIL may be a planarizing layer. The filling layer FIL may be an organic film formed of an acrylic resin, an epoxy resin, a phenolic resin, a polyamide resin, a polyimide resin, or the like.

The cover layer CVL may be disposed on the optical layer OPL. The cover layer CVL may be a glass substrate or a polymer resin such as, for example, a resin. In an example in which the cover layer CVL is the glass substrate, the cover layer CVL may be attached onto the filling layer FIL. In this case, the filling layer FIL may serve to adhere the cover layer CVL. In an example in which the cover layer CVL is the glass substrate, the cover layer CVL may serve as an encapsulation substrate. In an example in which the cover layer CVL is the polymer resin such as, for example, the resin, the cover layer CVL may be directly applied onto the filling layer FIL.

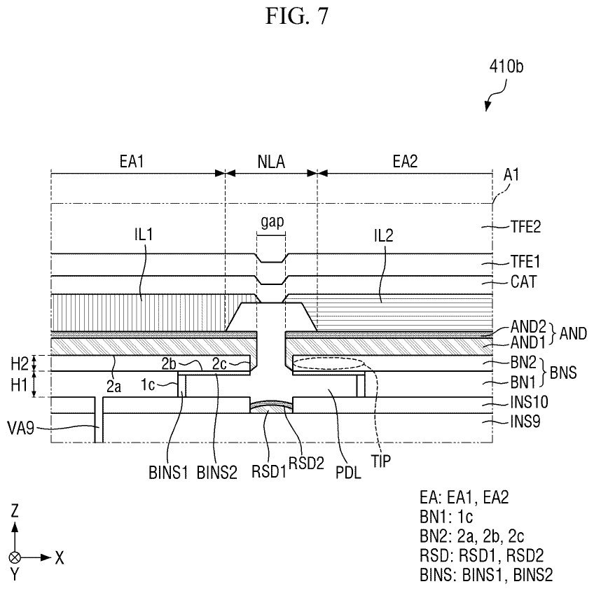

FIG. 7 is an enlarged cross-sectional view of area A1 of FIG. 5 according to another embodiment.

Referring to FIG. 7, a display panel 410b according to another embodiment is different from the display panel 410 described herein in that a bank insulating layer BINS includes a first bank insulating layer BINS1 and a second bank insulating layer BINS2. Hereinafter, a difference between the display panel 410 and the display panel 410b will be described in detail.

In some embodiments, the first bank insulating layer BINS1 may be positioned on the side surface 1c of the first bank layer BN1. The first bank insulating layer BINS1 may have the same structure and characteristics as the bank insulating layer BINS of the display panel 410. That is, the first bank insulating layer BINS1 may entirely cover the side surface 1c of the first bank layer BN1, and may be in entire contact with the side surface 1c of the first bank layer BN1.

The first bank insulating layer BINS1 may be formed on the side surface 1c of the first bank layer BN1 by injecting fluorine-based gas or oxygen gas or simultaneously injecting fluorine-based gas and oxygen gas in a subsequent process after the bank structure BNS is formed in a manufacturing process of the display panel 410b. As an example, the first bank insulating layer BINS1 may include aluminum fluoride (AlFx) and aluminum oxide fluoride (AlOₓF_{y}).

In some embodiments, the second bank layer BN2 may include an upper surface 2a, a lower surface 2b, and a side surface 2c. The upper surface 2a may be a surface facing the pixel electrode AND, the lower surface 2b may be a surface opposing the upper surface 2a, and the side surface 2c may be a surface connecting the upper surface 2a and the lower surface 2b to each other.

The second bank insulating layer BINS2 according to another embodiment may be positioned on the lower surface 2b of the second bank layer BN2. The second bank insulating layer BINS2 may entirely cover the lower surface 2b of the second bank layer BN2, and may be in entire contact with the lower surface 2b of the second bank layer BN2.

The second bank insulating layer BINS2 may be formed on the lower surface 2b of the second bank layer BN2 by injecting oxygen gas or simultaneously injecting oxygen gas or fluorine-based oxygen in a subsequent process after the bank structure BNS is formed in the manufacturing process of the display panel 410b. That is, the first bank insulating layer BINS1 and the second bank insulating layer BINS2 may be formed simultaneously in the same process. As an example, the second bank insulating layer BINS2 may include titanium dioxide (Ti0₂). Other overlapping descriptions will be omitted.

The second bank insulating layer BINS2 may be positioned to overlap the tip of the second bank layer BN2. For convenience of explanation, it has been illustrated in FIG. 7 that the second bank insulating layer BINS2 is formed to have the same thickness, but embodiments of the present disclosure are not limited thereto. The second bank insulating layer BINS2 may cover the lower surface 2b of the second bank layer BN2 positioned in a portion overlapping the tip of the second bank layer BN2 and have various thicknesses. For example, the second bank insulating layer BINS2 may have various thicknesses at respective portions of the second bank insulating layer BINS2 in contact with the lower surface 2b of the second bank layer BN2. In some aspects, the second bank insulating layer BINS2 may overlap the light emitting layer IL in the third direction (Z-axis direction).

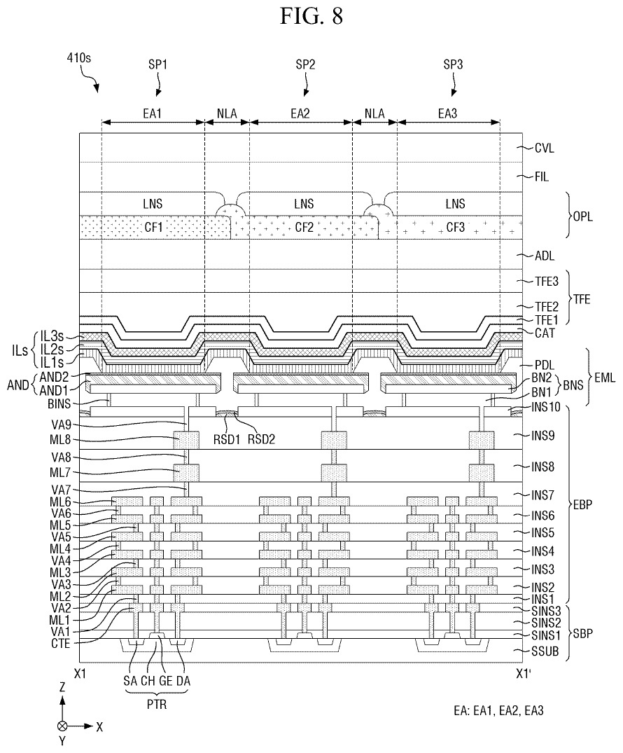

FIG. 8 is a schematic cross-sectional view of a display panel according to another embodiment taken along line X1-X1′ in FIG. 4.

Referring to FIG. 8, a light emitting layer ILs of a display panel 410s according to another embodiment is different from the light emitting layer IL of the display panel 410 described herein in that the light emitting layer IL of the display panel 410s is entirely formed in a portion overlapping the emission area EA and the non-emission area NLA. Hereinafter, a difference between the display panel 410 and the display panel 410s will be described in detail.

The light emitting layer ILs according to another embodiment may have a tandem structure including a plurality of first to third light emitting layers ILIs, IL2s, and IL3s that emit different light. For example, the first light emitting layer ILls may emit light of a first color, the second light emitting layer IL2s may emit light of a second color, and the third light emitting layer IL3s may emit light of a third color. The first light emitting layer ILIs, the second light emitting layer IL2s, and the third light emitting layer IL3s may be sequentially stacked.

The first light emitting layer ILIs may have a structure in which a first hole transporting layer, a first organic light emitting layer emitting the light of the first color, and a first electron transporting layer are sequentially stacked. The second light emitting layer IL2s may have a structure in which a second hole transporting layer, a second organic light emitting layer emitting the light of the second color, and a second electron transporting layer are sequentially stacked. The third light emitting layer IL3s may have a structure in which a third hole transporting layer, a third organic light emitting layer emitting the light of the third color, and a third electron transporting layer are sequentially stacked.

The light emitting layer ILs according to another embodiment may be positioned to overlap the bank structure BNS and the bank insulating layer BINS in the third direction Z, and may also be positioned to overlap the first residual pattern RSD1 and the second residual pattern RSD2. Other overlapping descriptions will be omitted.

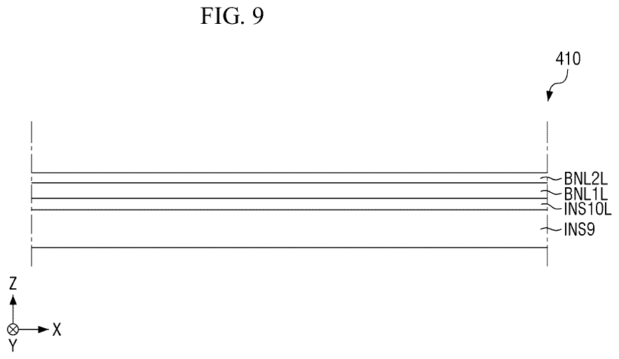

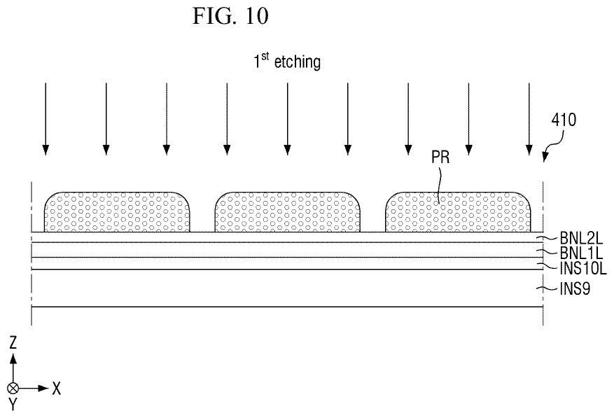

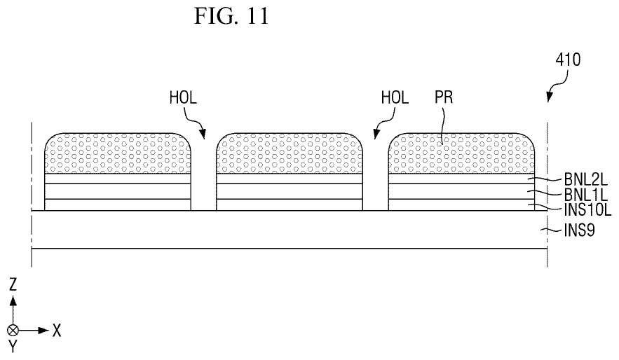

FIGS. 9 to 17 are cross-sectional views sequentially illustrating manufacturing processes of a bank structure BNS, pixel electrodes AND, and a pixel defining layer PDL of a display panel 410 according to an embodiment.

Example aspects of a method and processes supported by aspects of the present disclosure are described with reference to FIGS. 9 to 17. In the descriptions of the method and processes herein, the operations may be performed in a different order than the order shown and/or described, or the operations may be performed in different orders or at different times. Certain operations may also be left out of the methods and processes, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIGS. 9 to 11, the process may include entirely forming a tenth interlayer material layer INS10L on the ninth interlayer insulating layer INS9, and entirely forming a first bank material layer BNLIL and a second bank material layer BNL2L on the tenth interlayer material layer INS10L. Although not illustrated in FIGS. 9 to 11, the process may include disposing the ninth interlayer insulating layer INS9 on the semiconductor backplane SBP and the first to eighth interlayer insulating layers INS1 to INS8 and the first to eighth metal layers ML1 to ML8 of the light emitting element backplane EBP, and a detailed structure thereof is the same as that described herein with reference to FIG. 5. A detailed description thereof will be omitted.

Subsequently, the process may include forming photoresists PR on the second bank material layer BNL2L. In an example, a plurality of photoresists PR may be formed, and the plurality of photoresists PR may be spaced apart from each other.

Next, the process may include performing a first etching process (1^{st} etching) using the plurality of photoresists PR as a mask. As an example, the first etching process (1^{st} etching) may be a dry etching process.

In the present process, the process may include isotropically removing the tenth interlayer material layer INS10L, the first bank material layer BNLIL, and the second bank material layer BNL2L in portions where the photoresists PR are not formed. In some aspects, holes HOL may be formed in portions where the tenth interlayer material layer INS10L, the first bank material layer BNLIL, and the second bank material layer BNL2L are removed, and the ninth interlayer insulating layer INS9 may be exposed in portions overlapping the holes HOL.

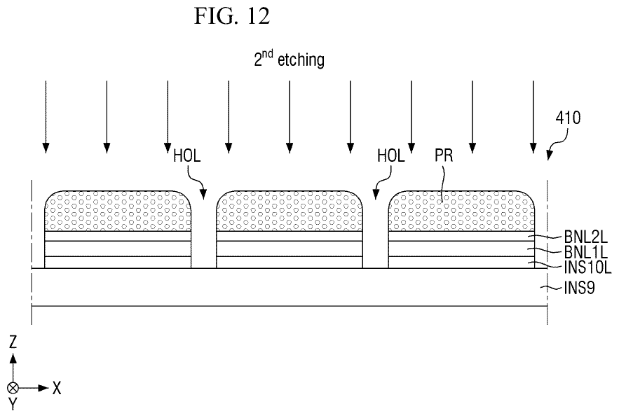

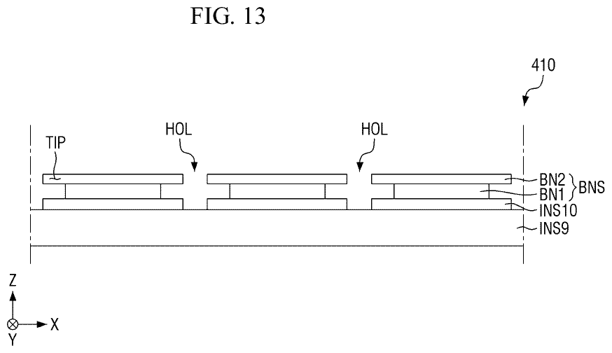

Subsequently, referring to FIGS. 12 and 13, the process may include forming photoresists PR in the same portions as the first etching process (1^{st} etching), and the process may include performing a second etching process (2^{nd} etching) using a plurality of photoresists PR as a mask. As an example, the second etching process (2^{nd} etching) may be a wet etching process.

In the present process, the tenth interlayer material layer INS10L, the first bank material layer BNL1L, and the second bank material layer BNL2L overlapping inner sides of the holes HOL may be anisotropically removed. Specifically, the first bank material layer BNL1L according to an embodiment may include a material having a higher etch rate than the second bank material layer BNL2L and the tenth interlayer material layer INS10L. Accordingly, through the second etching process (2^{nd} etching), the first bank material layer BNLIL may have a side surface depressed (recessed) more than the second bank material layer BNL2L and the tenth interlayer material layer INS10L in the first direction X. In other words, a side surface of the second bank material layer BNL2L may protrude more than the side surface of the first bank material layer BNLIL in the first direction X.

In the present process, the tenth interlayer material layer INS10L, the first bank material layer BNLIL, and the second bank material layer BNL2L may be formed in shapes of the tenth interlayer insulating layer INS10 and the bank structure BNS including the first bank layer BN1 and the second bank layer BN2 illustrated in FIG. 5. That is, the second bank layer BN2 may have a tip TIP protruding more than the side surface of the first bank layer BN1, and an undercut may be formed between the side surface of the first bank layer BN1 and the tip TIP of the second bank layer BN2.

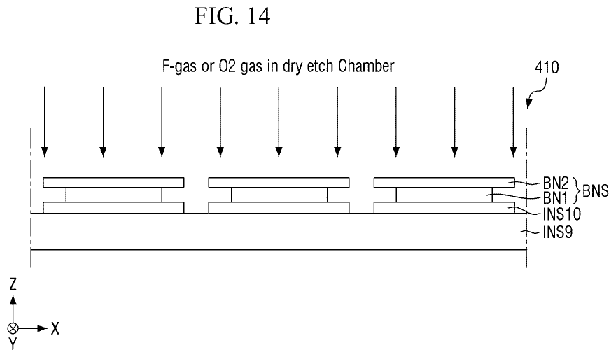

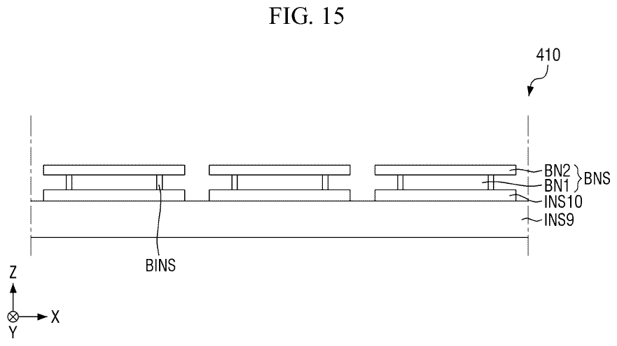

Next, referring to FIGS. 14 and 15, the process may include moving the display panel 410 to a dry etch chamber, and injecting fluorine-based gas, oxygen gas, or fluorine-based gas and oxygen gas into the display panel 410.

The process may include forming a bank insulating layer BINS on the side surface of the first bank layer BN1. As described herein with reference to FIG. 5, the first bank layer BN1 according to an embodiment may include aluminum. In general, aluminum ions may easily form stable ionic bonds with fluorine-based ions. Accordingly, the process may easily form the bank insulating layer BINS on the side surface of the first bank layer BN1 without another separate process. The bank insulating layer BINS may cover the entire side surface of the first bank layer BN1.

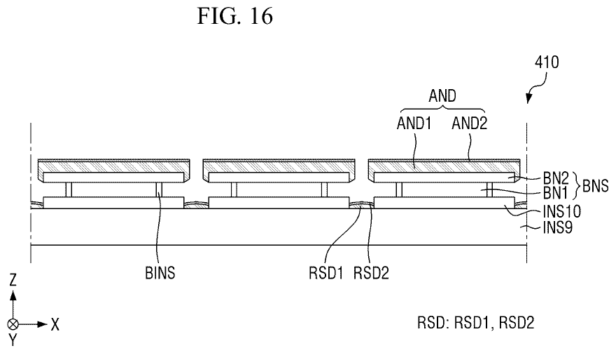

Subsequently, referring to FIG. 16, the process may include forming pixel electrodes AND on the second bank layer BN2. The pixel electrodes AND may be formed using a sputtering process or a thermal deposition method. Materials forming the pixel electrodes AND according to an embodiment may be formed such that the materials are spaced apart from each other on a plurality of bank structures BNS without a separate etching process because the second bank layer BN2 includes the tip TIP. Accordingly, in the display panel 410 according to an embodiment, a gap between the pixel electrodes may be reduced, and accordingly, a high-resolution display device may be implemented.

However, in some embodiments, the material forming the pixel electrode AND may also be positioned on the ninth interlayer insulating layer INS9 in a portion that does not overlap the bank structure BNS. The material forming the pixel electrode AND, formed on the ninth interlayer insulating layer INS9 in the portion that does not overlap the bank structure BNS, may be formed in a shape of the residual pattern RSD illustrated in FIG. 5.

According to embodiments, the pixel electrode AND may include a first layer AND1 and a second layer AND2, and accordingly, the residual pattern RSD may include a first residual pattern RSD1 and a second residual pattern RSD2.

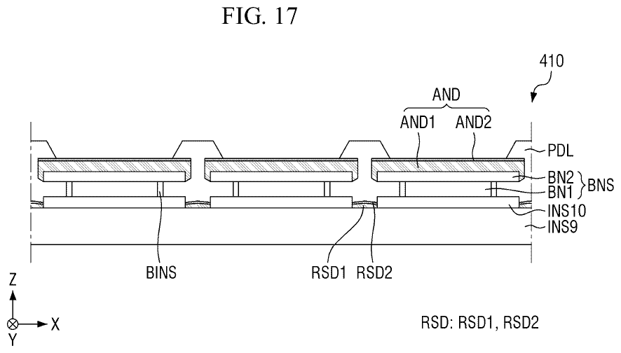

Next, referring to FIG. 17, the process may include forming a pixel defining layer PDL filling the undercut of the bank structure BNS and covering the residual pattern RSD. The pixel defining layer PDL may cover edges of the pixel electrodes AND.

Subsequently, although not illustrated in FIG. 17, the process may include manufacturing the display panel 410 by sequentially stacking the light emitting layers IL, the common electrode CAT, the encapsulation layer TFE, the adhesive layer ADL, and the optical layer OPL of FIG. 5. The light emitting layers IL, the common electrode CAT, the encapsulation layer TFE, the adhesive layer ADL, and the optical layer OPL are the same as those described herein with reference to FIG. 5, and a detailed description thereof will thus be omitted.

The invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising an emission area and a non-emission area;
a first bank layer positioned on the emission area of the substrate;
a first bank insulating layer positioned on a side surface of the first bank layer;
a second bank layer positioned on the first bank layer and comprising a tip protruding more than the side surface of the first bank layer toward the non-emission area;
a pixel electrode positioned on the second bank layer;
a light emitting layer positioned on the pixel electrode;
a residual pattern positioned on the non-emission area of the substrate and spaced apart from the pixel electrode, wherein the residual pattern and the pixel electrode comprise a same material; and
a pixel defining layer positioned on the residual pattern and covering the first bank layer, the second bank layer, and the pixel electrode.

2. The display device of claim 1, wherein the light emitting layer overlaps the first bank layer and the second bank layer in a direction perpendicular to the substrate.

3. The display device of claim 2, wherein:
an undercut is formed between the side surface of the first bank layer and the tip of the second bank layer, and
the undercut overlaps the light emitting layer in the direction perpendicular to the substrate.

4. The display device of claim 3, wherein a height of the first bank layer is greater than a height of the second bank layer.

5. The display device of claim 4, wherein the first bank layer and the second bank layer include different respective metals or alloys.

6. The display device of claim 1, wherein the first bank insulating layer entirely covers the side surface of the first bank layer.

7. The display device of claim 6, wherein the first bank insulating layer overlaps the light emitting layer in a direction perpendicular to the substrate.

8. The display device of claim 7, wherein the first bank insulating layer comprises fluorine ions.

9. The display device of claim 8, wherein the first bank insulating layer comprises either aluminum fluoride or aluminum oxide fluoride.

10. The display device of claim 1, wherein:
the second bank layer comprises a first surface facing the pixel electrode and a side surface facing the non-emission area, and
the pixel electrode covers the side surface of the second bank layer.

11. The display device of claim 10, wherein the pixel electrode is in contact with the side surface of the second bank layer.

12. The display device of claim 11, wherein:
the second bank layer further comprises a second surface opposing the first surface, and
a second bank insulating layer is positioned on the second surface in a portion overlapping the tip of the second bank layer.

13. The display device of claim 12, wherein the second bank insulating layer overlaps the light emitting layer in a direction perpendicular to the substrate, and
the second bank insulating layer comprises titanium oxide.

14. The display device of claim 1, wherein the pixel defining layer entirely covers the first bank insulating layer and the tip of the second bank layer.

15. The display device of claim 1, wherein the pixel electrode comprises:
a first layer disposed on the second bank layer and comprising metal; and
a second layer disposed on the first layer and comprising transparent conductive oxide (TCO).

16. The display device of claim 15, wherein:
the residual pattern comprises a first residual pattern and a second residual pattern, wherein the first residual pattern and the first layer comprise a same first material, and the second residual pattern and the second layer comprise a same second material, and
the second residual pattern covers the first residual pattern.

17. A method for manufacturing a display device, comprising:
forming a first bank layer on a substrate and forming a second bank layer on the first bank layer;
removing portions of the second bank layer and the first bank layer;
etching a portion of the first bank layer such that the second bank layer comprises a tip protruding more than a side surface of the first bank layer;
forming a bank insulating layer on the side surface of the first bank layer; and
forming a pixel electrode on the second bank layer and forming a residual pattern on the substrate.

18. The method for manufacturing a display device of claim 17, wherein the forming of the bank insulating layer comprises injecting fluorine ion gas or fluorine ion gas and oxygen gas.

19. The method for manufacturing a display device of claim 18, wherein in the forming of the bank insulating layer, the bank insulating layer entirely covers the side surface of the first bank layer.

20. The method for manufacturing a display device of claim 19, wherein the forming of the pixel electrode on the second bank layer and the forming of the residual pattern on the substrate comprises disconnecting a material forming the pixel electrode by the tip of the second bank layer, wherein disconnecting the material comprises separating the material into the pixel electrode and the residual pattern.
